(19) United States
(12) Patent Application Publication
(10) Pub. No.: US 2004/0080435 A1
(43) Pub. Date: Apr. 29, 2004

(54) Data input system and method

(75) Inventor: Chia-Chi Feng, Macau (MO)

Correspondence Address: THE LAW OFFICES OF MIKIO ISHIMARU, 1110 SUNNYVALE-SARATOGA ROAD, SUITE A1, SUNNYVALE, CA, 94087, US

(73) Assignee: Culture.Com Technology (MACAU) Ltd., Macau (MO)

(21) Appl. No.: 10/389,548

(22) Filed: Mar. 13, 2003

(30) Foreign Application Priority Data
Oct. 25, 2002 (TW) 91125400

(51) Int. Cl. H03M 11/00; H03K 17/94; H03M 7/00

(52) U.S. Cl. 341/22

(57) ABSTRACT

A data input system and a data input method are provided and applied to an electronic product. The data input system serves as an input device for an electronic product, whereby a user can use a plurality of keys to input data or commands including numerals, symbols, English letters and/or Chinese characters to the electronic product, so as to properly operate the electronic product and to execute desirable functions. With different parts of each key being designated with different functions in a manner as to achieve satisfactory performance and functionality through the use of a small number of keys, the electronic product with the data input system can thereby be desirably fabricated with reduced size and costs.

### FIELD OF THE INVENTION

The present invention relates to data input systems and methods, and more particularly, to a data input system and a data input method, for allowing a user to utilize real keys and virtual keyboards for inputting data to electronic products.

### BACKGROUND OF THE INVENTION

Keyboards or keys serve as important input devices for electronic products, whereby users can operate keys for inputting data or commands to the electronic products, and for executing programs or functions internally constructed in the electronic products.

Generally, if an electronic product is merely used for providing internal functions thereof, keys formed for the electronic product may be less than twelve in number; however, if the electronic product is also adapted for receiving data inputted by a user, including numerals, symbols, English letters and/or Chinese characters, at least twelve keys are required for use with the electronic product; for example, a keypad 100 of a conventional telephone shown in FIG. 1 includes twelve keys, and a keypad 200 of a cellular phone shown in FIG. 2 has more than twelve keys. As a result, an electronic product normally needs to be dimensioned sufficiently for accommodating a certain number (twelve or more) of keys, and thus hardly reduced in size thereby not in favor of profile miniaturization.

Therefore, it is desired to provide a data input system and a data input method for use with an electronic product, whereby a user can use less than twelve keys to properly operate the electronic product, thereby reducing size and fabrication costs of the electronic product.

### SUMMARY OF THE INVENTION

A primary objective of the present invention is to provide a data input system and a data input method, applied to an electronic product, for allowing a user to use less than ten real keys and/or at least one virtual keyboard to input data or commands including numerals, symbols, English letters and/or Chinese characters to the electronic product, so as to properly operate the electronic product and to execute desirable functions.

In accordance with the foregoing and other objectives, the present invention proposes a data input system and a data input method, applied to an electronic product, for allowing a user to use a plurality of keys to input data to the electronic product. The data input system comprises: a key set, a processing module and a display screen, wherein the key set is composed of more than one and less than ten keys, and different parts of each key are designated with different functions. The processing module provides at least one virtual keyboard displayed on the display screen, for allowing a user to operate the keys to input data or commands via the virtual keyboard to the electronic product.

In proceeding of the data input method, the user first presses different parts of a single key or a plurality of keys of the key set to execute desirable functions provided by the electronic product and to input data or commands including numerals, symbols, English letters and/or Chinese characters to the electronic product. Then, the processing module receives signals generated from keys operated by the user, and resolves contents of the signals, for example, execution of functions, and input of data or commands, whereby the resolved contents of the signals are displayed on the display screen to allow the user to properly operate the electronic product. With different parts of each key being designated with different functions in a manner as to achieve satisfactory performance and functionality through the use of a small number of keys, the electronic product with the data input system can thereby be desirably fabricated with reduced size and costs.

### BRIEF DESCRIPTION OF THE DRAWINGS

The present invention can be more fully understood by reading the following detailed description of the preferred embodiments, with reference made to the accompanying drawings wherein:

FIG. 1 (PRIOR ART) is a schematic diagram showing a keypad of a conventional telephone;

FIG. 2 (PRIOR ART) is a schematic diagram showing a keyboard of a cellular phone;

FIG. 3 is a system block diagram showing basic architecture of a data input system according to a preferred embodiment of the invention;

FIG. 4 is a flowchart showing process steps of a data input method in the use of the data input system according to the invention;

FIG. 5 is a system block diagram showing an embodiment of basic architecture of an electronic product with the data input system shown in FIG. 3;

FIG. 6 is a schematic diagram showing an embodiment of a real key set of the data input system shown in FIG. 5;

FIG. 7 is a flowchart showing process steps of a preferred embodiment of a data input method for inputting numerals in the use of the data input system shown in FIG. 5;

FIG. 8 is a flowchart showing process steps of another preferred embodiment of the data input method for inputting numerals in the use of the data input system shown in FIG. 5;

FIG. 9 is a system block diagram showing another embodiment of basic architecture of an electronic product with the data input system shown in FIG. 3;

FIG. 10 is a schematic diagram showing an embodiment of a real key set of the data input system shown in FIG. 9;

FIG. 11 is a schematic diagram showing a picture of a virtual keyboard for inputting English letters displayed on a display screen;

FIG. 12 is a schematic diagram showing a picture of a virtual keyboard for inputting Chinese characters displayed in the display screen;

FIG. 13 is a schematic diagram showing a picture of another virtual keyboard for inputting Chinese characters displayed in the display screen;

FIG. 14 is a schematic diagram showing a picture of inputted Chinese characters displayed in the display screen;

FIG. 15 is a flowchart showing process steps of a preferred embodiment of a data input method for inputting numerals in the use of the data input system shown in FIG. 9;

FIG. 16 is a flowchart showing process steps of another preferred embodiment of the data input method for inputting numerals in the use of the data input system shown in FIG. 9;

FIG. 17 is a flowchart showing process steps of a preferred embodiment of the data input method for inputting English letters in the use of the data input system shown in FIG. 9;

FIG. 18 is a flowchart showing process steps of a preferred embodiment of the data input method for inputting Chinese characters in the use of the data input system shown in FIG. 9; and

FIG. 19 is a flowchart showing process steps of another preferred embodiment of the data input method for inputting Chinese characters in the use of the data input system shown in FIG. 9.

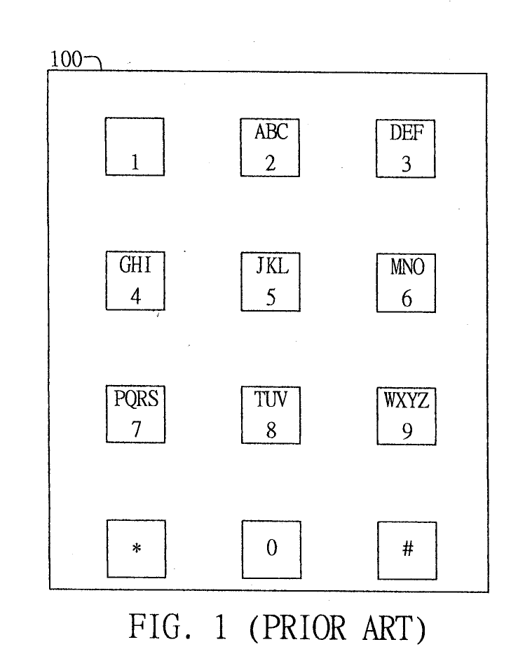

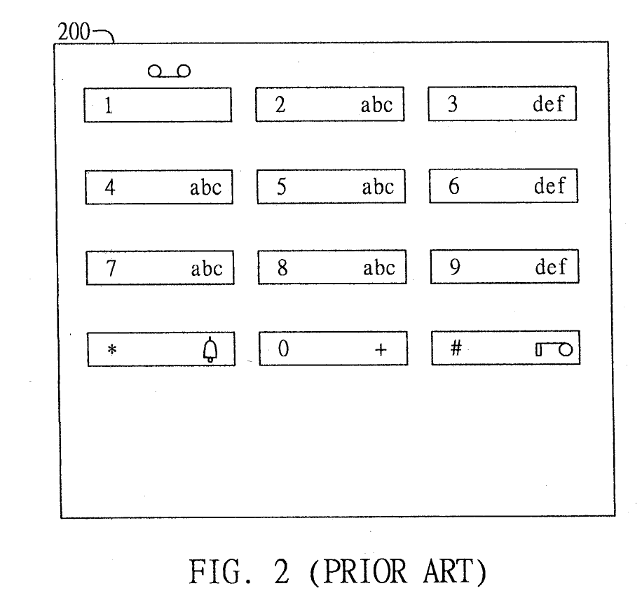

### DETAILED DESCRIPTION OF THE PREFERRED EMBODIMENT

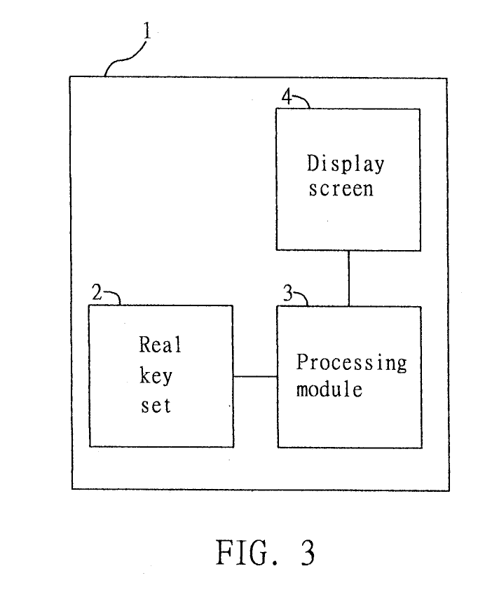

FIG. 3 illustrates basic architecture of a data input system 1 according to a preferred embodiment of the invention. As shown in the drawing, the data input system 1 is applied to an electronic product (not shown), and at least includes a real key set 2, a processing module 3 and a display screen 4, wherein the processing module 3 is connected to the real key set 2 and the display screen 4.

The real key set 2 is composed of less than ten real keys (not shown). A user may press a single key or sequentially press a plurality of keys of the real key set 2 to execute internally-constructed functions provided by the electronic product or to activate virtual keyboards, so as to thereby input data or commands including numerals, symbols, English letters and/or Chinese characters to the electronic product.

The processing module 3 is used to receive signals generated by pressing one or more keys of the real key set 2, and to resolve content or meaning represented by the signals, for example, to execute internally-constructed functions provided by the electronic product, or to activate one or more virtual keyboards for inputting data or commands. Moreover, the processing module 3 displays the resolved content or meaning of the signals on the display screen 4, for allowing the user to properly operate the electronic product.

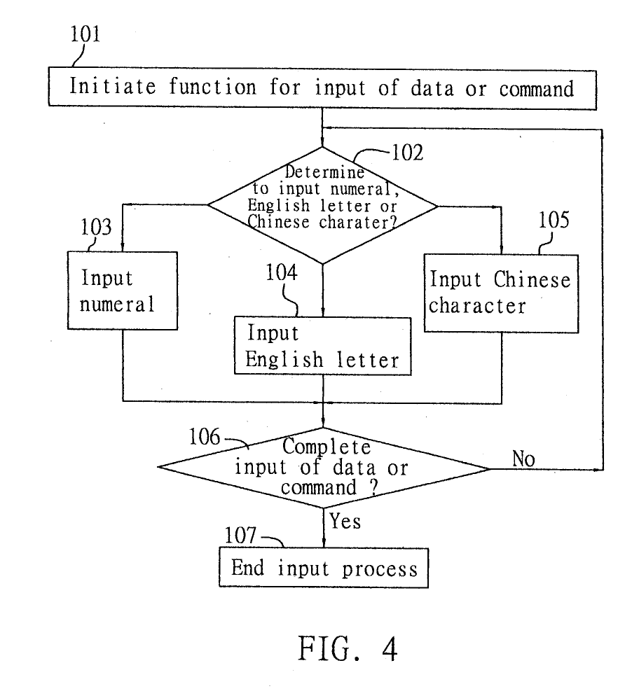

FIG. 4 illustrates process steps of a data input method in the use of the data input system 1 according to the invention. As shown in the drawing, in step 101, a user presses a single key or a plurality of keys of the real key set 2 to initiate functions related to input of data or commands including numerals, symbols, English letters and/or Chinese characters. Then, it proceeds to step 102.

In step 102, the user determines to input numerals, English letters or Chinese characters; for inputting numerals, it proceeds to step 103; for inputting English letters, it proceeds to step 104; for inputting Chinese characters, it proceeds to step 105.

In step 103, the user performs input of numerals. Then, it proceeds to step 106.

In step 104, the user performs input of English letters. Then, it proceeds to step 106.

In step 105, the user performs input of Chinese characters. Then, it proceeds to step 106.

In step 106, the user determines if input of data or commands is complete; if yes, it proceeds to step 107; if no, it returns to step 102.

In step 107, the process for inputting data or commands ends.

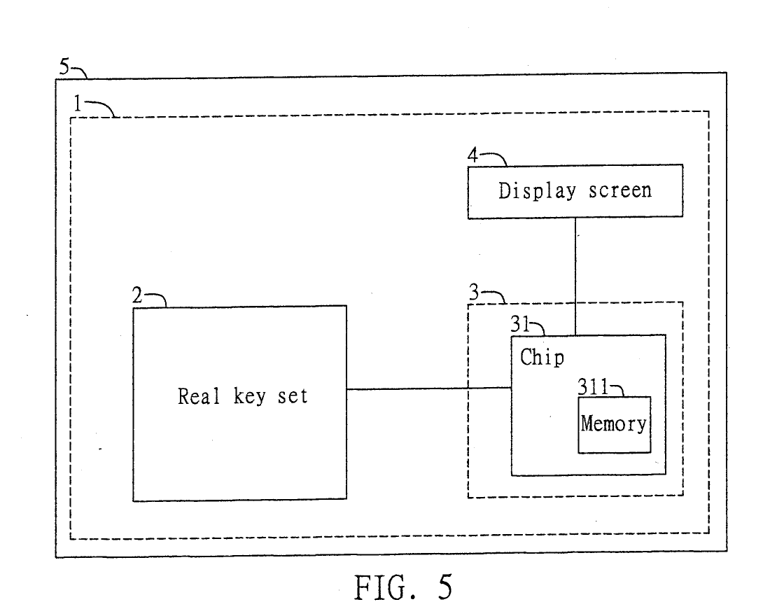

FIG. 5 illustrates an embodiment of basic architecture of an electronic product 5 with the data input system 1 according to the invention. The electronic product 5 may be an electronic-book (e-book) reader, personal digital assistant (PDA), or cellular phone. The data input system 1 may serve as an input device for the electronic product 5, and the processing module 3 may be a chip 31 having a memory 311 such as flash memory, read-only memory (ROM) or others.

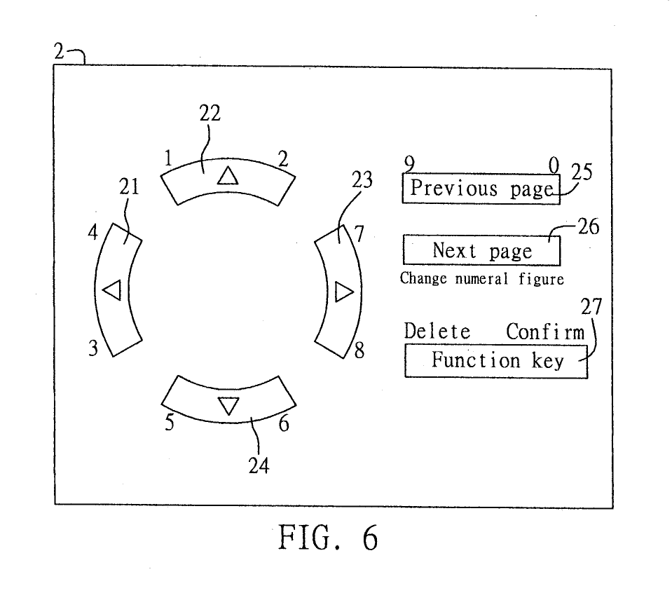

FIG. 6 illustrates an embodiment of a real key set 2 of the data input system 1 shown in FIG. 5. As shown in FIG. 6, the real key set 2 is composed of seven keys 21, 22, 23, 24, 25, 26, 27. The key 21 is used to move a cursor leftwards and to input numerals 3 and 4; the key 22 is used to move the cursor upwards and to input numerals 1 and 2; the key 23 is used to move the cursor rightwards and to input numerals 7 and 8; the key 24 is used to move the cursor downwards and to input numerals 5 and 6; the key 25 is used to read a previous page and input numerals 9 and 0; the key 26 is used to read a next page and change numeral figures; the key 27 is used to select a function, confirm inputted numerals or letters, and delete inputted numerals or letters.

When a user operates the key 27 to select a numeral-input function, the keys 21, 22, 23, 24, 25 activates functions thereof related to input of numerals, and closes functions thereof for moving the cursor and for reading a previous page; the key 26 switches to a function for changing numeral figures, and closes a function for reading a next page; and the key 27 activates functions for confirming or deleting inputted numerals. For example, the user may press a lower part of the key 21 to input a numeral 3, and allows input of the numeral 3 to be automatically confirmed in about five seconds or manually confirmed by pressing a right part of the key 27. As the user presses the key 21 for inputting the numeral 3, the processing module 3 of the data input system 1 receives a signal generated by pressing the key 21, and resolves content or meaning of the signal to thereby display the inputted numeral 3 on the display screen 4.

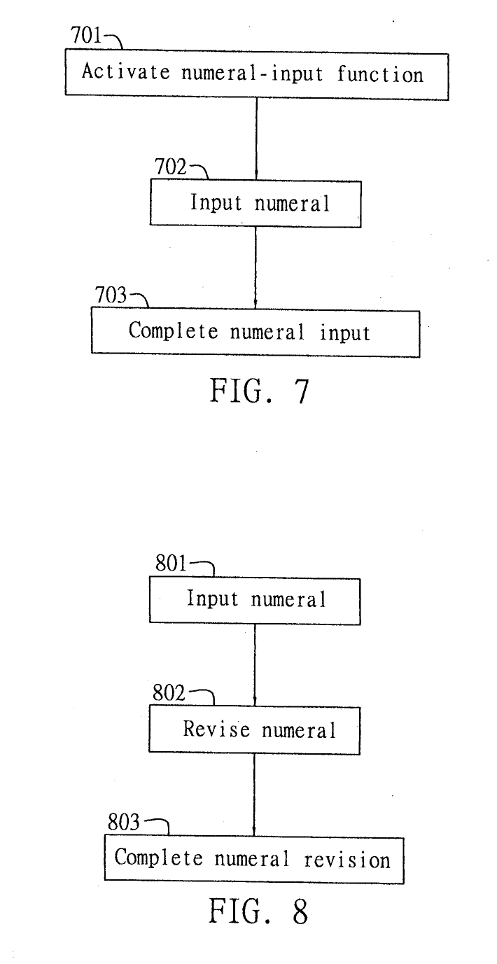

FIG. 7 illustrates process steps of a preferred embodiment of a data input method for inputting numerals in the use of the data input system 1 shown in FIG. 5. As shown in FIG. 7, first in step 701, a user operates the key 27 to select a numeral-input function, allowing the keys 21, 22, 23, 24, 25, 26, 27 to activate functions thereof related to input of numerals. Then, it proceeds to step 702.

In step 702, for example of inputting a number 405, the user sequentially presses an upper part of the key 21, a right part of the key 25 and a left part of the key 24 to input numerals 4, 0, 5; then, input of the numeral 5 is allowed to be automatically confirmed in about five seconds or manually confirmed by pressing a right part of the key 27, such that input of the number 405 is complete. Therefore, in respect of inputting a multi-figure number, it only needs to confirm the last inputted numeral to complete input of the multi-figure number. Then, it proceeds to step 703.

In step 703, the numeral-input process ends.

FIG. 8 illustrates process steps of another preferred embodiment of the data input method for inputting numerals in the use of the data input system 1 shown in FIG. 5. As shown in FIG. 8, first in step 801, a user operates the real key set 2 to input a number 231. Then, it proceeds to step 802.

In step 802, if the user tends to revise the number 231 to be 531, as the intended-revised numeral 2 is away by two figures from a cursor displayed in the display screen 4, the user needs to press the key 26 for two times to move the cursor to the numeral 2. The user presses a left part of the key 27 to delete the numeral 2, and then presses a left part of the key 24 to input a numeral 5, allowing input of the numeral 5 to be automatically confirmed in about five seconds or manually confirmed by pressing a right part of the key 27. Then, it proceeds to step 803.

In step 803, with the number 231 being revised to be 531, the number-revision process ends.

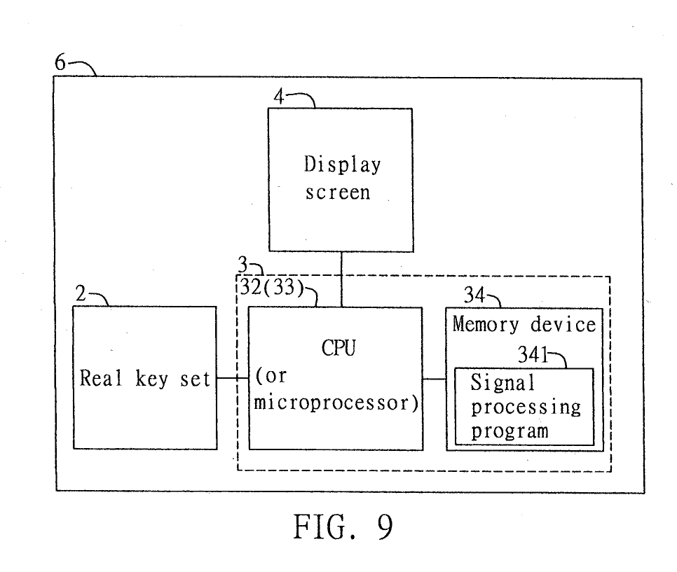

FIG. 9 illustrates another embodiment of basic architecture of an electronic product 6 with the data input system 1 shown in FIG. 3. The electronic product 6 may be an electronic-book (e-book) reader, personal digital assistant (PDA), or cellular phone. The data input system 1 may serve as an input device for the electronic product 6. The processing module 3 may be composed of a central processing unit (CPU) 32 or microprocessor 33, and a memory device 34 having a signal processing program 341; the CPU 32 or microprocessor 33 may execute the signal processing program 341 of the memory device 34; the memory device 34 may be a flash memory, read-only memory (ROM), universal serial bus (USB) interface memory or others.

FIG. 10 illustrates an embodiment of a real key set 2 of the data input system 1 shown in FIG. 9. As shown in FIG. 10, the real key set 2 is composed of eight keys 201, 202, 203, 204, 205, 206, 207, 208. The key 201 is used to move a cursor leftwards and to input a numeral 0; the key 202 is used to move the cursor upwards and to input a numeral 1; the key 203 is used to move the cursor rightwards and to input a numeral 2; the key 204 is used to move the cursor downwards and to input a numeral 4; the key 205 is used to perform an insertion operation and to input a numeral 8; the key 206 is used to confirm inputted numerals or letters, and to delete inputted numerals or letters; the key 207 is used to perform number addition or deduction, and to convert between English capital and lowercase letters; the key 208 is used as a power switch and to select a function.

When a user operates the key 208 to select a numeral-input function, the keys 201, 202, 203, 204, 205, 207 activates functions thereof related to input of numerals and number calculation (i.e. addition and deduction), and closes functions thereof for moving the cursor and for converting between English capital and lowercase letters. For example, the user may press the key 201 to input a numeral 0, and then press a right part of the key 206 to confirm input of the numeral 0.

In respect of numerals 3, 5, 6, 7, 9, for example, as the numeral 3 is equal to 1 plus 2, the user may first press the key 202 to input a numeral 1, then press a left part (marked “+”) the key 207 to perform addition, and further press the key 203 to input a numeral 2 in a manner as to add the numerals 1 and 2 to obtain the numeral 3. Moreover, as the numeral 7 is equal to 8 minus 1, the user may first press the key 205 to input a numeral 8, then press a right part (marked “−”) of the key 207 to perform deduction, and further press the key 202 to input a numeral 1 in a manner as to deduct the numeral 1 from the numeral 8 to obtain the numeral 7. This therefore allows input of any numeral from 0 to 9 to be implemented.

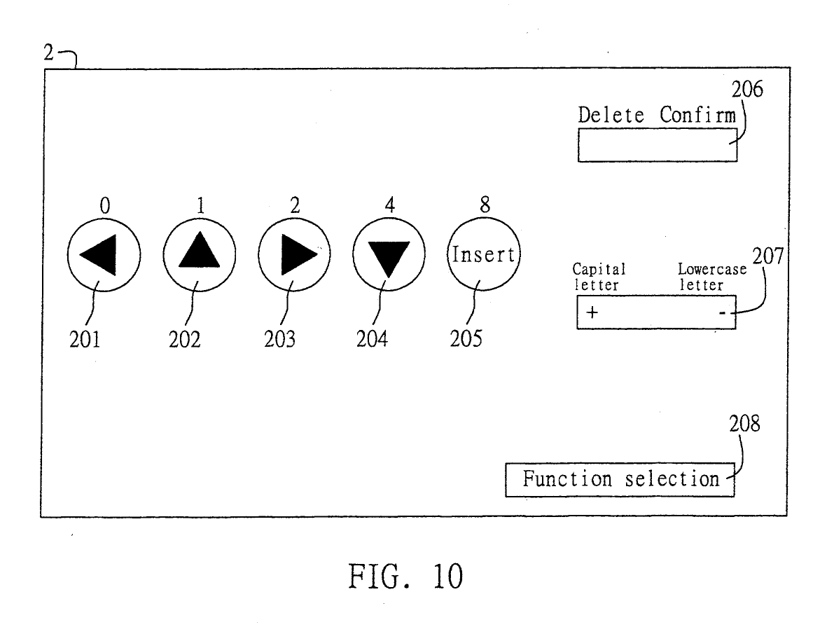

When the user operates the key 208 to select a function of inputting English letters, the keys 201, 202, 203, 204, 207 activates functions thereof for moving the cursor and for converting between English capital and lowercase letters, and displays a picture of a virtual keyboard for inputting English letters shown in FIG. 11 on the display screen 4. Thereby, the user may operate the keys 201, 202, 203, 204 to move the cursor to an intended-selected letter, then press a left/right part of the key 207 to determine a capital/lowercase letter, and finally press a right part of the key 206 to confirm input of the selected letter.

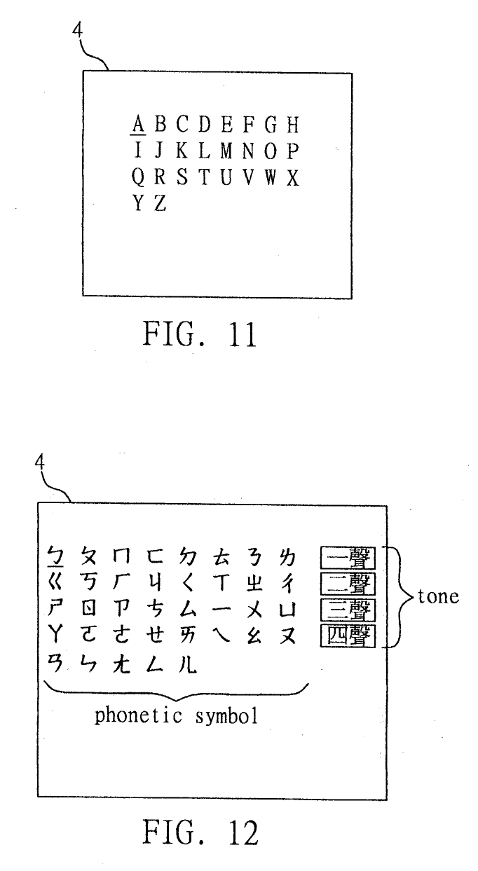

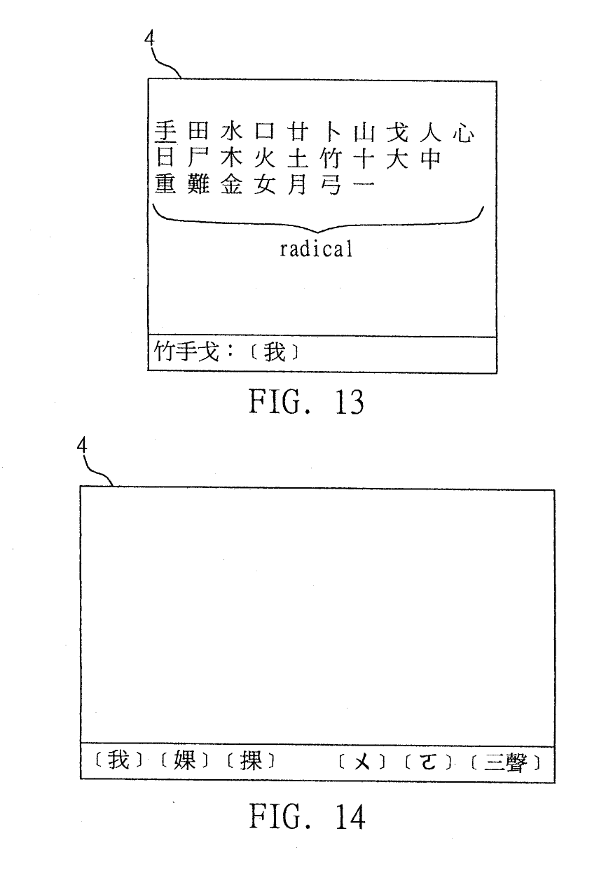

When the operates the key 208 to select a function of inputting Chinese characters, the keys 201, 202, 203, 204 activates functions thereof for moving the cursor, and displays a picture of a virtual keyboard for inputting Chinese characters shown in FIG. 12 or 13 on the display screen 4. Thereby, the user may operate the keys 201, 202, 203, 204 to move the cursor to an intended-selected phonetic symbol or tone, and press a right part of the key 206 to confirm input of the selected phonetic symbol or tone. Alternatively, the user may operate the keys 201, 202, 203, 204 to move the cursor to an intended-selected radical, and press a right part of the key 206 to confirm input of the selected radical. Then, a group of Chinese characters formed by combining the selected phonetic symbols and tones, or by combining the selected radicals are displayed on the screen display 4 (as shown in FIG. 14), allowing the user to operate the keys 201, 202, 203, 204, 206 to select an intended Chinese character.

FIG. 15 illustrates process steps of a preferred embodiment of a data input method for inputting numerals in the use of the data input system 1 shown in FIG. 9. As shown in FIG. 15, first in step 901, a user operates the key 208 of the real key set 2 to select a numeral-input function, so as to allow the keys 201, 202, 203, 204, 205, 207 to activate functions thereof related to input of numerals. Then, it proceeds to step 902.

In step 902, for example of inputting a number 304, the user sequentially presses the key 202, a left part of the key 207 and the key 203 to add numerals 1 and 2 to thus obtain a numeral 3; then, the user presses the key 201 to input a numeral 0; and finally, the user presses the key 204 to input a numeral 4, thereby completing input of the number 304. Then, it proceeds to step 903.

In step 903, the numeral-input process ends.

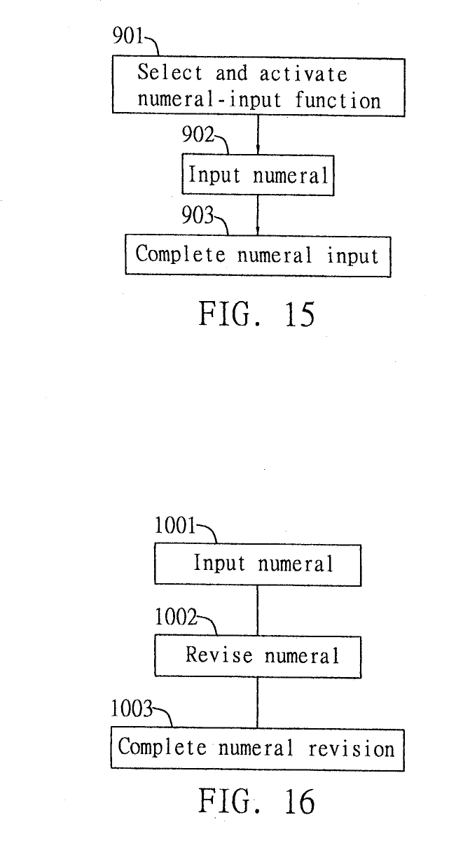

FIG. 16 illustrates process steps of another preferred embodiment of the data input method for inputting numerals in the use of the data input system 1 shown in FIG. 9. As shown in FIG. 16, first in step 1001, a user operates the real key set 2 to input a number 431. Then, it proceeds to step 1002.

In step 1002, in order to revise the number 431 to be 421, first, the user operates the key 208 to activate cursor-moving and insertion functions of the keys 201, 202, 203, 204, 205. The user presses the key 201 once to move the cursor from the numeral 1 to the numeral 3, and then presses a left part of the key 206 to delete the numeral 3, such that the cursor moves back to the numeral 1. Then, the user operates the key 205 to perform insertion, and presses the key 203 to insert a numeral 2 between the numerals 4 and 1, thereby revision of the number 431 to be 421. Then, it proceeds to step 1003.

In step 1003, the number-revision process ends.

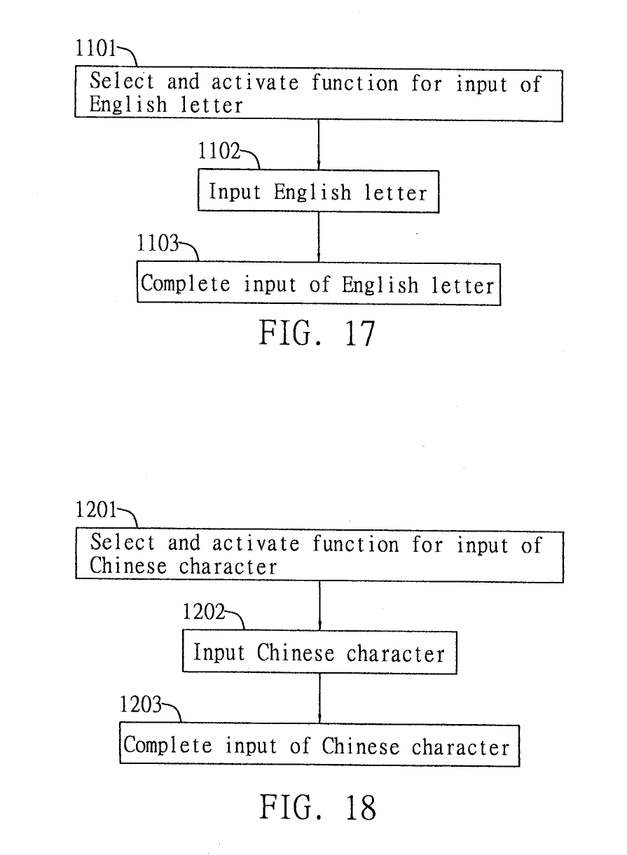

FIG. 17 illustrates process steps of a preferred embodiment of the data input method for inputting English letters in the use of the data input system 1 shown in FIG. 9. As shown in FIG. 17, first in step 1101, a user operates the key 208 of the real key set 2 to select a function of inputting English letters, so as to allow the keys 201, 202, 203, 204, 207 to activate functions of moving the cursor and converting between English capital and lowercase letters, and to display a picture of a virtual keyboard for inputting English letters displayed on the display screen 4 with the cursor being initially located at a letter “A” as shown in FIG. 11. Then, it proceeds to step 1102.

In step 1102, for example of inputting an English word “Cat”, the user first presses the key 203 twice to move the cursor to a letter “C”, and presses a left part of the key 207 for inputting capital letters, so as to obtain the letter “C”. Then, the user presses the key 201 twice to move the cursor back to the letter “A”, and presses a right part of the key 207 for inputting lowercase letters, so as to obtain a small letter “a”. Thereafter, the user presses the key 204 twice and the key 203 for three times to move the cursor from the letter “A” to a letter “T”, and then presses the right part of the key 207 for inputting lowercase letters, so as to obtain a small letter “t”. Finally, the user presses a right part of the key 206 to confirm input of the word “Cat”. Then, it proceeds to step 1103.

In step 1103, after the word “Cat” is inputted, the English-word input process ends.

FIG. 18 illustrates process steps of a preferred embodiment of the data input method for inputting Chinese characters in the use of the data input system 1 shown in FIG. 9. As shown in FIG. 18, first in step 1201, a user operates the key 208 of the real key set 2 to select a function of inputting Chinese characters, so as to allow the keys 201, 202, 203, 204 to activate functions of moving the cursor, and to display a picture of a virtual keyboard for inputting Chinese characters displayed in the display screen 4 with the cursor being initially located at a radical “ [symbol] ” as shown in FIG. 13. Then, it proceeds to step 1202.

In step 1202, for example of inputting a Chinese character “ [symbol] ” that is composed of three radicals including “ [symbol] ”, “ [symbol] ” and “ [symbol] ”, user first presses the key 204 once and the key 203 for five times to move the cursor from the radical “ [symbol] ” to the radical “ [symbol] ”, and presses a right part of the key 206 to confirm input of the radical “ [symbol] ”. Then, the user presses the key 202 once and the key 201 for five times to move the cursor from the radical “ [symbol] ” to the radical “ [symbol] ”, presses the right part of the key 206 to confirm input of the radical “ [symbol] ”. Thereafter, the user presses the key 203 for seven times to move the cursor from the radical “ [symbol] ” to the radical “ [symbol] ”, presses the right part of the key 206 to confirm input of the radical “ [symbol] ”. After the radicals “ [symbol] ”, “ [symbol] ” and “ [symbol] ” are entered, the Chinese character “ [symbol] ” is displayed on the display screen 4, as shown in FIG. 13. Then, it proceeds to step 1203.

In step 1203, after the Chinese character “ [symbol] ” is obtained, the Chinese-character input process ends.

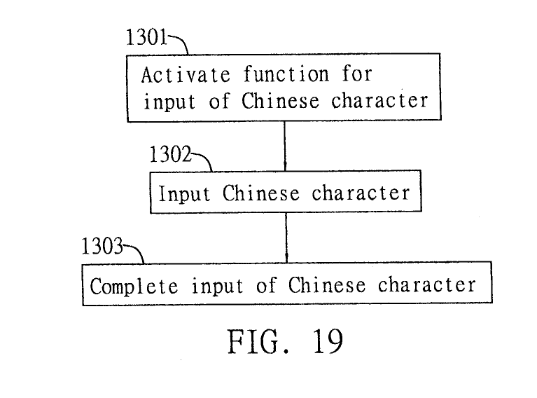

FIG. 19 illustrates process steps of another preferred embodiment of the data input method for inputting Chinese characters in the use of the data input system 1 shown in FIG. 9. As shown in FIG. 19, first in step 1301, a user operates the key 208 of the real key set 2 to select a function of inputting Chinese characters, so as to allow the keys 201, 202, 203, 204 to activate functions of moving the cursor, and to display a picture of a virtual keyboard for inputting Chinese characters displayed in the display screen 4 with the cursor being initially located at a phonetic symbol “ [symbol] ” as shown in FIG. 12. Then, it proceeds to step 1302.

In step 1302, for example of inputting a Chinese character “ [symbol] ”that is composed of phonetic symbols “ [symbol] ” and “ [symbol] ” and a tone “ [symbol] ”, the user first presses the key 204 twice and the key 203 for six times to move the cursor from the phonetic symbol “ [symbol] ” to the phonetic symbol “ [symbol] ”, and presses a right part of the key 206 to confirm input of the phonetic symbol “ [symbol] ”. Then, the user presses the key 204 once and the key 201 for five times to move the cursor from the phonetic symbol “ [symbol] ” to the phonetic symbol “ [symbol] ”, and presses the right part of the key 206 to confirm input of the phonetic symbol “ [symbol] ”. Thereafter, the user presses the key 203 for seven times and the key 202 once to move the cursor from the phonetic symbol “ [symbol] ” to the tone “ [symbol] ”, and presses the right part of the key 206 to confirm input of the tone “ [symbol] ”. After the phonetic symbols “ [symbol] ” and “ [symbol] ” and the tone “ [symbol] ” are entered, corresponding Chinese characters “ [symbol] ”, “ [symbol] ” and “ [symbol] ” are displayed on the display screen 4 as shown in FIG. 14, with the cursor being initially located at the Chinese character “ [symbol] ”, and the user only needs to press the right part of the key 206 to input the Chinese character “ [symbol] ”. Then, it proceeds to step 1303.

In step 1303, after the Chinese character “ [symbol] ” is obtained, the Chinese-character input process ends.

The above data input system and method according to the invention provide significant benefits. The data input system serves as an input device for an electronic product, whereby a user can use less than ten real keys and/or at least one virtual keyboard to input data or commands including numerals, symbols, English letters and/or Chinese characters to the electronic product, so as to properly operate the electronic product and to execute desirable functions. With different parts of each real key being designated with different functions in a manner as to achieve satisfactory performance and functionality through the use of a small number of keys, the electronic product with the data input system can thereby be desirably fabricated with reduced size and costs.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A data input method, applied to an electronic product, for allowing a user to use a plurality of keys to input data to the electronic product, wherein different parts of each of the keys are designated with different operative functions; the data input method comprising the steps of:
(1) selecting a function for inputting numerals, symbols or characters, if the numeral input function is selected, proceeding to step (2); if the symbol input function is selected, proceeding to step (3); if the character input function is selected, proceeding to step (4);
(2) activating functions of the keys related to input of numerals, for allowing the user to operate different parts of the keys to input intended numerals and/or to perform numeric calculations; then, proceeding to step (7);
(3) activating functions of the keys related to input of symbols, for allowing the user to operate different parts of the keys to input intended symbols; then, proceeding to step (7);
(4) determining to input Chinese or English characters, if to input Chinese characters, proceeding to step (5); if to input English characters, proceeding to step (6);
(5) selecting a Chinese-character input system for inputting Chinese characters, and activating functions of the keys related to input of Chinese characters, for allowing the user to operate different parts of the keys to input intended Chinese characters; then, proceeding to step (7);
(6) activating functions of the keys related to input of English characters, for allowing the user to operate different parts of the keys to input intended English characters; then, proceeding to step (7); and
(7) ending the data input method.

2. The data input method of claim 1, wherein in step (2), the user presses different parts of a single key to input numerals and/or perform numeric calculations.

3. The data input method of claim 1, wherein in step (2), the user presses continuously a plurality of keys to input numerals and/or perform numeric calculations.

4. The data input method of claim 1, wherein the functions of the keys related to input of numerals are selected from the group consisting of inputting arabic numerals, changing a numeral figure, numeric addition, numeric deduction, confirming input of a numeral, and deleting a numeral.

5. The data input method of claim 1, wherein the keys are in a number of more than one and less than ten.

6. The data input method of claim 1, wherein the functions of the keys related to input of symbols are selected from the group consisting of moving a cursor, selecting a symbol, and deleting a symbol.

7. The data input method of claim 1, wherein the Chinese-character input system is selected from the group at least consisting of a phonetic-symbol input system and a radical input system.

8. The data input method of claim 7, wherein in step (5), for the phonetic-symbol input system, the functions of the keys related to input of Chinese characters are selected from the group consisting of moving a cursor, selecting a phonetic symbol, and deleting a phonetic symbol.

9. The data input method of claim 7, wherein in step (5), for the radical input system, the functions of the keys related to input of Chinese characters are selected from the group consisting of moving a cursor, selecting a radical, and deleting a radical.

10. The data input method of claim 1, wherein the functions of the keys related to input of English characters are selected from the group consisting of moving a cursor, selecting an English letter, deleting an English letter, and converting between English capital/lowercase letters.

11. The data input method of claim 1, wherein the electronic product is selected from the group consisting of an electronic-book reader, personal digital assistant, and cellular phone.

12. A data input system, applied to an electronic product, for allowing a user to use a plurality of keys to input data to the electronic product; the data input system comprising:
a key set composed of a plurality of keys in a number of more than one and less than ten, wherein different parts of each of the keys are designated with different operative functions, so as to allow the user to operate different parts of the keys to input data including numerals, symbols and/or characters;
a processing module for receiving signals generated from keys operated by the user, and for resolving contents of the signals to accordingly allow the user to perform data input; and
a display screen for displaying contents of the signals resolved by the processing module.

13. The data input system of claim 12, wherein the processing module provides at least one virtual keyboard displayed on the display screen, for allowing the user to input numerals, symbols and/or characters via the virtual keyboard.

14. The data input system of claim 12, wherein the keys provide functions related to input of numerals by which the user inputs intended numerals and/or performs numeric calculations, and the functions are selected from the group consisting of inputting arabic numerals, changing a numeral figure, numeric addition, numeric deduction, confirming input of a numeral, and deleting a numeral.

15. The data input system of claim 12, wherein the keys provide functions related to input of symbols by which the user inputs intended symbols, and the functions are selected from the group consisting of moving a cursor, selecting a symbol, and deleting a symbol.

16. The data input system of claim 12, wherein the keys provide functions related to input of Chinese characters by which the user executes an intended Chinese-character input system for inputting Chinese characters.

17. The data input system of claim 16, wherein the Chinese-character input system is selected from the group at least consisting of a phonetic-symbol input system and a radical input system.

18. The data input system of claim 17, wherein for the phonetic-symbol input system, the functions of the keys related to input of Chinese characters are selected from the group consisting of moving a cursor, selecting a phonetic symbol, and deleting a phonetic symbol.

19. The data input system of claim 17, wherein for the radical input system, the functions of the keys related to input of Chinese characters are selected from the group consisting of moving a cursor, selecting a radical, and deleting a radical.

20. The data input system of claim 12, wherein the keys provide functions related to input of English letters by which the user inputs intended English letters, and the functions are selected from the group consisting of moving a cursor, selecting an English letter, deleting an English letter, and converting between English capital/lowercase letters.
